(19) United States
(12) Patent Application Publication
(10) Pub. No.: US 2017/0077218 A1
(43) Pub. Date: Mar. 16, 2017

(54) SEMICONDUCTOR DEVICE

(71) Applicant: Kabushiki Kaisha Toshiba, Tokyo (JP)

(72) Inventors: Yukie Nishikawa, Nonoichi Ishikawa (JP); Yasuhiko Akaike, Kanazawa Ishikawa (JP); Masaki Okazaki, Nonoichi Ishikawa (JP)

(21) Appl. No.: 15/042,747

(22) Filed: Feb. 12, 2016

(30) Foreign Application Priority Data
Sep. 11, 2015 (JP) 2015-179160

(51) Int. Cl. H01L 29/06; H01L 29/868

(52) U.S. Cl. CPC H01L 29/0619; H01L 29/868

(57) ABSTRACT

Provided is a semiconductor device including a first electrode, a second electrode, a semiconductor substrate having a first plane, a second plane, a first conductivity-type first region, and a plurality of second conductivity-type second regions provided around the first electrode, the second regions being in contact with the first plane, at least a portion of the semiconductor substrate being provided between the first electrode and the second electrode, a first insulating film provided on or above the second regions, the first insulating film including positive charges, and a second insulating film provided on or above the second regions, second insulating film including negative charges.

### CROSS-REFERENCE TO RELATED APPLICATION

This application is based upon and claims the benefit of priority from Japanese Patent Application No. 2015-179160, filed on Sep. 11, 2015, the entire contents of which are incorporated herein by reference.

### FIELD

Embodiments described herein relate generally to a semiconductor device.

### BACKGROUND

As factors of degrading reliability of a semiconductor device, there is known changes in device characteristics due to charges included in insulating films, interface charges existing at interfaces between a semiconductor layer and insulating films, extraneous charges invading from the outside of the device, and the like. In some cases, charges included in the insulating films move in the semiconductor device during the operation or standby of the semiconductor device to decrease a breakdown voltage of the semiconductor device or to increase leakage current thereof.

### BRIEF DESCRIPTION OF THE DRAWINGS

FIG. 1 is a schematic cross-sectional diagram of a semiconductor device according to a first embodiment.

FIG. 2 is a schematic plan diagram of the semiconductor device according to the first embodiment.

FIG. 3 is a schematic cross-sectional diagram of a semiconductor device according to a first comparative example.

FIG. 4 is a schematic cross-sectional diagram of a semiconductor device according to a second comparative example.

FIG. 5 is an explanation diagram of functions and effects of the semiconductor device according to the first embodiment.

FIG. 6 is an explanation diagram of functions and effects of the semiconductor device according to the first embodiment.

FIG. 7 is an explanation diagram of functions and effects of the semiconductor device according to the first embodiment.

FIG. 8 is a schematic cross-sectional diagram of a semiconductor device according to a second embodiment.

FIG. 9 is a schematic cross-sectional diagram of a semiconductor device according to a third embodiment.

FIG. 10 is a schematic cross-sectional diagram of a semiconductor device according to a fourth embodiment.

### DETAILED DESCRIPTION

A semiconductor device according to an embodiment includes a first electrode, a second electrode, a semiconductor substrate having a first plane, a second plane, a first conductivity-type first region, and a plurality of second conductivity-type second regions provided around the first electrode, the second regions being in contact with the first plane, at least a portion of the semiconductor substrate being provided between the first electrode and the second electrode, a first insulating film provided on or above the second regions, the first insulating film including positive charges, and a second insulating film provided on or above the second regions, second insulating film including negative charges.

Hereinafter, embodiments of the present invention will be described with reference to the drawings. In addition, in the description hereinafter, the same or similar components are denoted by the same reference numerals, and redundant description of the component or the like which is described once is omitted.

In this specification, the expression of n⁺ type, n type, and n⁻ type denotes that concentrations of n type impurity concentrations are lowered in the order of n⁺ type, n type, and n⁻ type. In addition, the expression of p⁺ type and p type denotes that p type impurity concentrations are lowered in the order of p⁺ type and p type.

### First Embodiment

A semiconductor device according to this embodiment includes a first electrode, a second electrode, a semiconductor substrate having a first plane, a second plane, a first conductivity-type first region, and a plurality of second conductivity-type second regions formed around the first electrode to be in contact with the first plane, at least a portion of the semiconductor substrate being formed between the first electrode and the second electrode, a first insulating film formed on or above the second regions to include positive charges, and a second insulating film formed on or above the second regions to include negative charges.

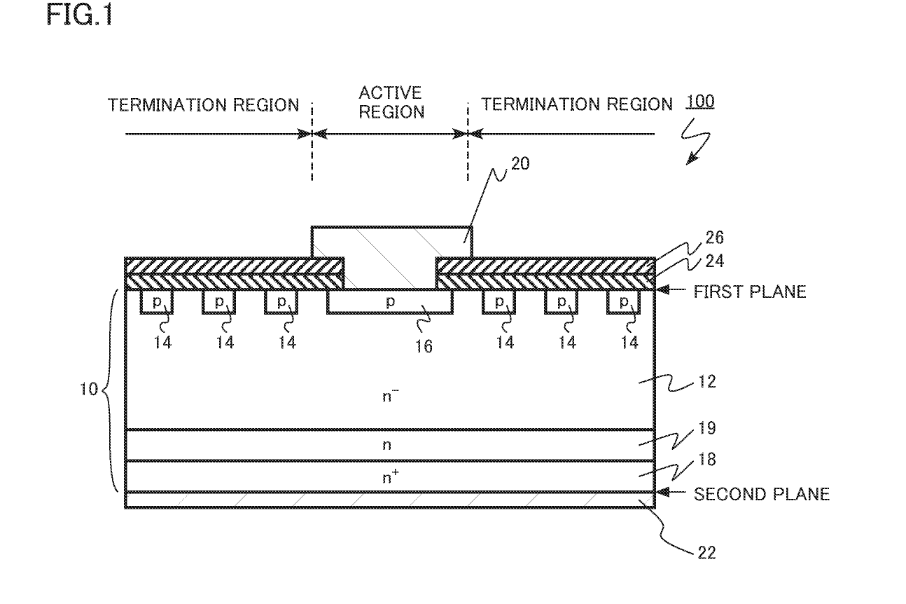

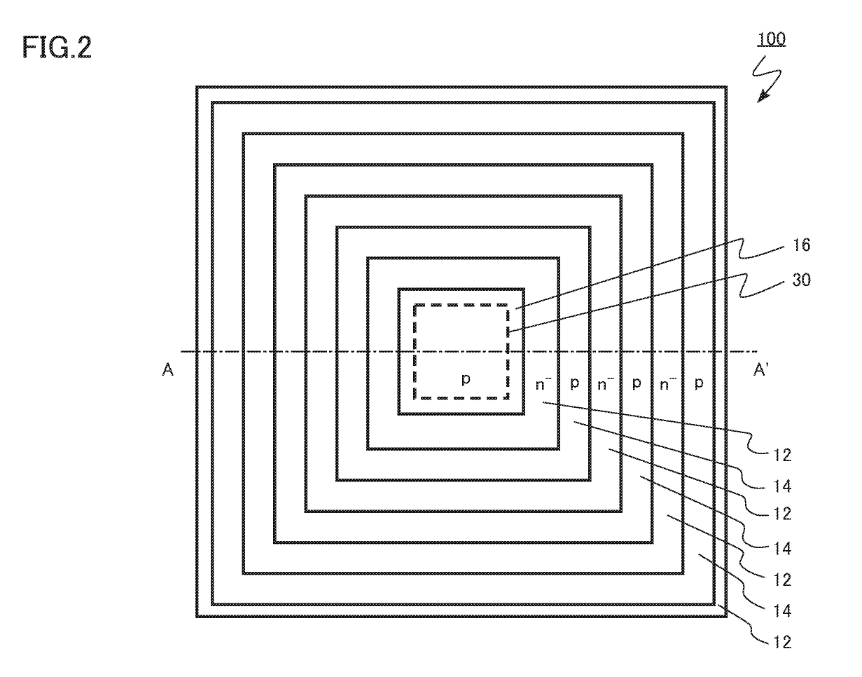

FIG. 1 is a schematic cross-sectional diagram of the semiconductor device according to the embodiment. FIG. 2 is a schematic plan diagram of the semiconductor device according to the embodiment. FIG. 2 illustrates a pattern of impurity regions on a front surface of a semiconductor substrate. FIG. 1 illustrates a cross section corresponding to an A-A′ cross section of FIG. 2. The semiconductor device according to the embodiment is a vertical type PIN diode 100. The PIN diode 100 is, for example, a high breakdown voltage diode having a breakdown voltage of 4.5 kV or more. The breakdown voltage is not limited to 4.5 kV or more, but for example, the embodiment may be applied to a semiconductor device requiring a breakdown voltage of 600 V or more.

The PIN diode 100 is configured to include an active region and a termination region surrounding the active region. The active region functions as a region where current flows mainly at the time of forward bias of the PIN diode 100. The termination region functions as a region of alleviating an intensity of an electric field applied to the end portion of the active region at the time of reverse bias of the PIN diode 100 to improve a device breakdown voltage of the PIN diode 100.

The PIN diode 100 is configured to include a silicon substrate (semiconductor substrate) 10, an anode electrode (first electrode) 20, a cathode electrode (second electrode) 22, a first interlayer insulating film (first insulating film) 24, and a second interlayer insulating film (second insulating film) 26. The semiconductor substrate 10 is configured to include an n⁻ type drift region (first region) 12, p type guard ring regions (second regions) 14, a p type anode region 16, an n⁺ type cathode region 18, and an n type buffer region 19.

The silicon substrate 10 has a first plane, and a second plane facing the first plane. In FIG. 1, the first plane is the surface in the upper portion of the figure, and the second plane is the surface in the lower portion of the figure. At least a portion of the silicon substrate 10 is formed between the anode electrode 20 and the cathode electrode 22.

The n⁺ type cathode region 18 is formed in the silicon substrate 10. The n⁺ type cathode region 18 is formed to be in contact with the second plane of the silicon substrate 10.

The n+ type cathode region 18 contains n type impurities. The n type impurity is, for example, phosphorus (P) or arsenic (As).

The n type buffer region 19 is formed in the silicon substrate 10. The n type buffer region 19 is formed to be in contact with the surface of the n⁺ type cathode region 18 facing the second plane. The n type buffer region 19 contains n type impurities. The n type impurity is, for example, phosphorus (P) or arsenic (As).

The n⁻ type drift region 12 is formed in the silicon substrate 10. The n⁻ type drift region 12 is formed between the n type buffer region 19 and the first plane.

The n⁻ type drift region 12 contains n type impurities. The n type impurity is, for example, phosphorus (P) or arsenic (As).

The p type anode region 16 is formed in the silicon substrate 10. The p type anode region 16 is formed in the active region. The p type anode region 16 is formed to be in contact with the first plane of the silicon substrate 10.

The p type anode region 16 contains p type impurities. The p type impurity is, for example, boron (B).

A plurality of the p type guard ring regions 14 are formed in the silicon substrate 10. The p type guard ring regions 14 are formed in the termination region. The p type guard ring regions 14 are formed to be in contact with the first plane of the silicon substrate 10. The p type guard ring regions 14 are formed between the n⁻ type drift region 12 and the first plane of the silicon substrate 10.

In addition, as illustrated in FIG. 2, the p type guard ring regions 14 are formed around the region 30 where the anode electrode 20 is in contact with the first plane of the silicon substrate 10 and the anode region 16. The p type guard ring regions 14 have a ring shape surrounding the region 30 and the anode region 16.

The p type guard ring regions 14 contain p type impurities. The p type impurity is, for example, boron (B).

In FIGS. 1 and 2, although the number of p type guard ring regions 14 is set to 3, the number of p type guard ring regions 14 is not necessarily limited to 3. The number of p type guard ring regions 14 is determined according to the breakdown voltage level or the like required for the PIN diode 100. The number of p type guard ring regions 14 is, for example, 10 or more and 30 or less.

In addition, in FIGS. 1 and 2, although the width and interval of p type guard ring regions 14 are set to constant values, the width or interval of p type guard ring regions 14 are not limited to the constant values. The width and interval of the p type guard ring regions 14 are determined according to the breakdown voltage level or the like required for the PIN diode 100. For example, the interval of p type guard ring regions 14 is set to be narrow at the side close to the active region and to be widened as being apart from the active region.

For example, the chip shape of the PIN diode 100 is a square about 10 mm on a side, the shape of the anode region 16 is a square about 7 mm on a side, and the width of the termination region around the anode region 16 is about 1.5 mm.

The first interlayer insulating film 24 is formed on the first plane of the silicon substrate 10. The first interlayer insulating film 24 is formed on the p type guard ring regions 14.

The first interlayer insulating film 24 includes positive charges in the film. The amount of positive charges is, for example, 1E10 cm⁻² or more 1E12 cm⁻² or less. The first interlayer insulating film 24 is, for example, an oxide film. The first interlayer insulating film 24 is, for example, a silicon oxide film.

The thickness of the first interlayer insulating film 24 is, for example, 0.1 μm or more and 2.0 nm or less.

The first interlayer insulating film 24 is, for example, a silicon oxide film formed by a chemical vapor deposition (CVD) method using tetraethyl orthosilicate (TEOS) as a source gas. The silicon film formed by the CVD method using TEOS as a source gas includes positive charges in the film.

The first interlayer insulating film 24 may be, for example, a silicon oxide film formed by a PECVD (Plasma Enhanced CVD) method using silane (SiH₄) as a source gas. The silicon oxide film formed by the PECVD method using silane (SiH₄) as a source gas includes positive charges in the film.

The second interlayer insulating film 26 is formed above the first plane of the silicon substrate 10. The second interlayer insulating film 26 is formed above the p type guard ring regions 14. In the embodiment, the second interlayer insulating film 26 is formed on the first interlayer insulating film 24 to be in contact with the first interlayer insulating film 24.

The second interlayer insulating film 26 includes negative charges in the film. The amount of negative charges is, for example, 1E10 cm⁻² or more 1E12 cm⁻² or less. The second interlayer insulating film 26 is, for example, an oxide film. The second interlayer insulating film 26 is, for example, a silicon oxide film.

The thickness of the second interlayer insulating film 26 is, for example, 0.1 μm or more and 2.0 μm or less.

The second interlayer insulating film 26 is, for example, a silicon oxide film formed by a high density plasma-CVD (HDP-CVD) method using silane (SiH₄) as a source gas. The silicon oxide film formed by the HDP-CVD method using silane (SiH₄) as a source gas includes negative charges in the film.

In the HDP-CVD method, sputtering is performed at the same time of film deposition. Therefore, particularly, the film deposition is suppressed at corners of the protrusions on the surface, so that the surface of the film becomes planer.

Polarities and amounts of the charges in the first interlayer insulating film 24 and the second interlayer insulating film 26 can be obtained by a capacitance-voltage (C-V) method. For example, a surface of a desired interlayer insulating film is exposed by etching, a metal electrode is formed thereon, and a shift in flat band voltage is measured by using the C-V method, so that the polarity and amount of charges can be obtained.

In a case where the first interlayer insulating film 24 is a silicon film formed by the CVD method using TEOS as a source gas and the second interlayer insulating film 26 is a silicon oxide film formed by the HDP-CVD method using silane (SiH₄) as a source gas, a carbon concentration of the first interlayer insulating film 24 is higher than that of the second interlayer insulating film 26. In addition, a moisture (OH) concentration of the first interlayer insulating film 24 is higher than that of the second interlayer insulating film 26.

The carbon concentrations of the first and second interlayer insulating films 24 and 26 may be measured by, for example, secondary ion mass spectrometry (SIMS). The moisture (OH) concentrations of the first and second interlayer insulating films 24 and 26 may be measured by, for example, fourier transform infrared spectroscopy (FTIR).

The anode electrode 20 is formed on the silicon substrate 10. The anode electrode 20 is formed to be in contact with a portion of the first plane of the silicon substrate 10.

The anode electrode 20 is formed to be in contact with the anode region 16. The contact between the anode electrode 20 and the anode region 16 is an ohmic contact.

The anode electrode 20 is a metal. The anode electrode 20 is a stacked film of, for example, titanium (Ti), titanium nitride (TiN), and aluminum (Al).

The cathode electrode 22 is formed to be in contact with the second plane of the silicon substrate 10.

The cathode electrode 22 is formed to be in contact with the cathode region 18. A contact between the cathode electrode 22 and the cathode region 18 is an ohmic contact.

The cathode electrode 22 is a metal. The cathode electrode 22 is a stacked film of, for example, titanium (Ti), nickel (Ni), and silver (Ag).

Next, functions and effects of the semiconductor device according to the embodiment will be described.

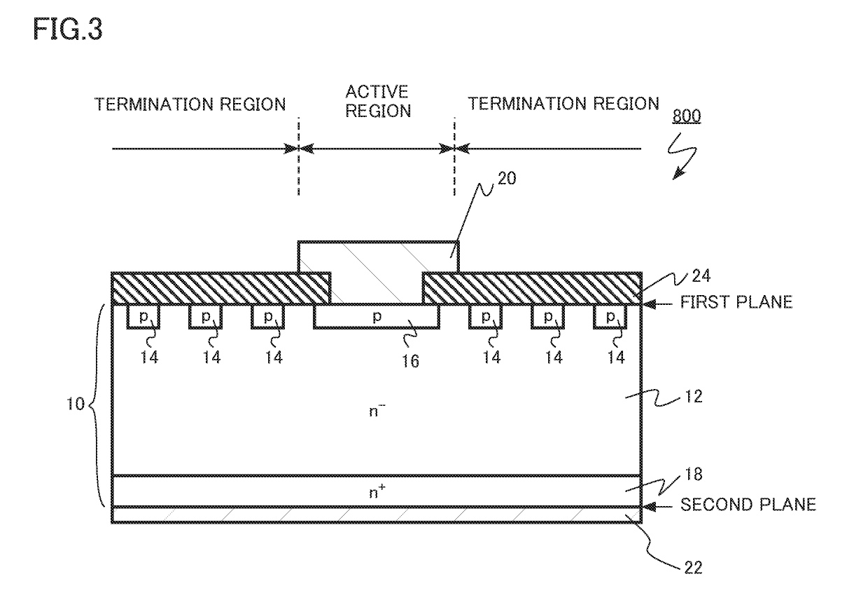

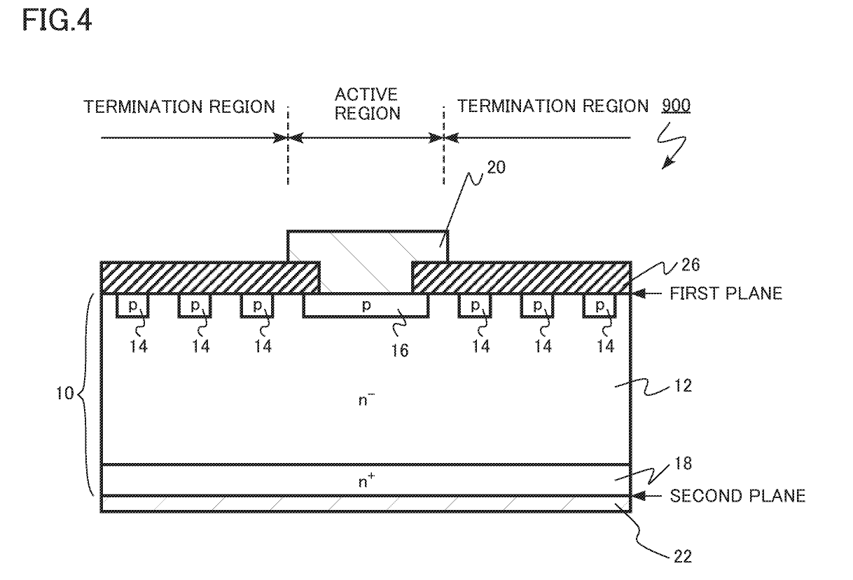

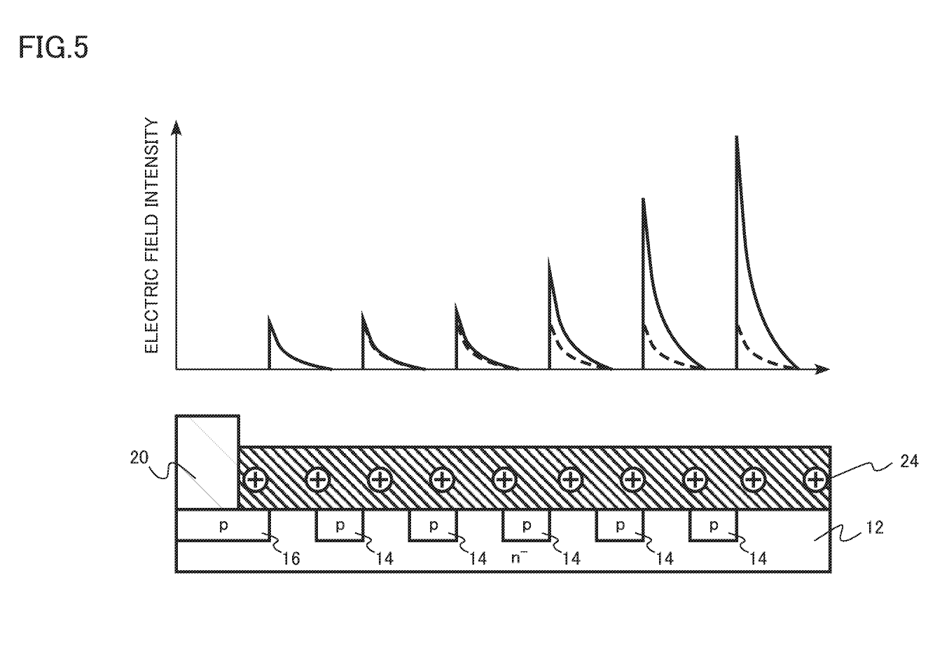

FIG. 3 is a schematic cross-sectional diagram of a semiconductor device according to a first comparative example. FIG. 4 is a schematic cross-sectional diagram of a semiconductor device according to a second comparative example. FIGS. 5, 6, and 7 are explanation diagrams of functions and effects of the semiconductor device according to the embodiment.

The semiconductor device according to the first comparative example is a vertical type PIN diode 800. The PIN diode 800 is different from the PIN diode 100 according to this embodiment in terms that the interlayer insulating film is a single-layered film of the first interlayer insulating film 24, that is, a single-layered film of the insulating film including positive charges. In addition, the thickness of the first interlayer insulating film 24 of the PIN diode 800 is equal to the total thickness of the first interlayer insulating film 24 and the second interlayer insulating film 26 of the PIN diode 100 according to the embodiment.

The semiconductor device according to the second comparative example is a vertical type PIN diode 900. The PIN diode 900 is different from the PIN diode 100 according to this embodiment in terms that the interlayer insulating film is a single-layered film of the second interlayer insulating film 26, that is, a single-layered film of the insulating film including negative charges. In addition, the thickness of the second interlayer insulating film 26 of the PIN diode 900 is equal to the total thickness of the first interlayer insulating film 24 and the second interlayer insulating film 26 of the PIN diode 100 according to the embodiment.

In the PIN diode 800 according to the first comparative example and the PIN diode 900 according to the second comparative example, in a bias & temperature (BT) test, a decrease in breakdown voltage or an increase in leakage current occurs. In the BT test, stress of high temperature and reverse bias is applied. On the other hand, in the PIN diode 100 according to the embodiment, although the BT test is performed in the same conditions, a decrease in breakdown voltage or a increase in leakage current is suppressed.

FIG. 5 is a schematic diagram illustrating an electric field intensity distribution at the time of reverse bias in the termination region of the first comparative example. The figure illustrates a schematic cross-sectional diagram of the termination region of the PIN diode 800 and the electric field intensity distribution. The dotted line indicates the electric field intensity distribution before applying stress, and the solid line indicates the electric field intensity distribution after applying stress.

The electric field intensity distribution before applying stress represents that the electric field intensity distribution is almost uniform in the termination region. On the other hand, the electric field intensity distribution after applying stress represents that the electric field intensity distribution is not uniform in the termination region. Particularly, in the outer circumferential portion of the termination region being apart from the active region, the electric field intensity becomes strong. In a case when an amount of positive charges included in the insulating film is large and the electric field intensity of the outer circumferential portion becomes larger than a threshold value, a decrease in breakdown voltage or an increase in leakage current of the PIN diode 800 occurs. Or, in a case when the influence of extraneous charges or interface charges are added to the influence of the positive charges included in the insulating film, the electric field intensity of the outer circumferential portion may exceed the threshold value, and a decrease in breakdown voltage or an increase in leakage current of the PIN diode 800 occurs.

It is considered that the change in electric field intensity distribution occurs because the positive charges in the first insulating film 24 are moved by the electric field applied to the first insulating film 24.

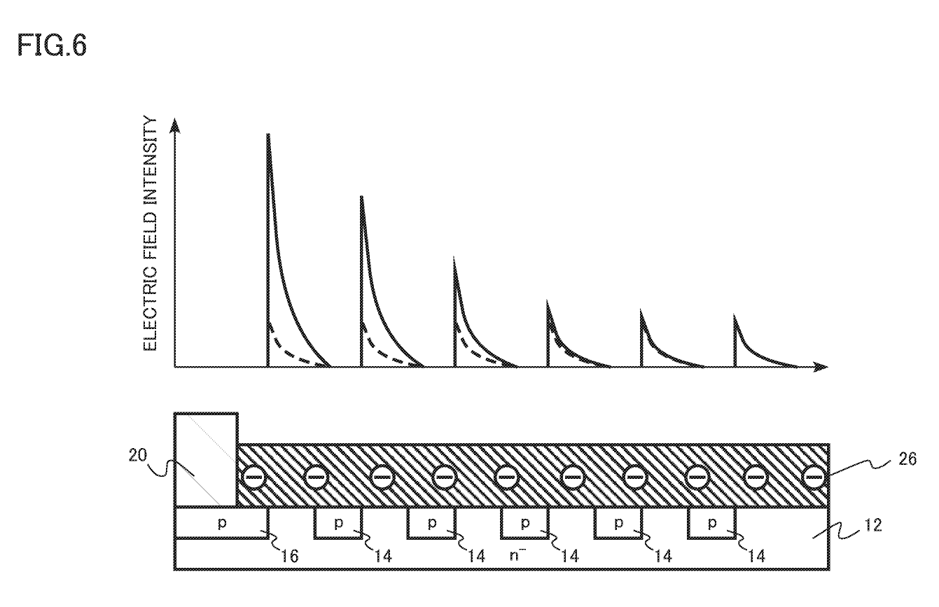

FIG. 6 is a schematic diagram illustrating an electric field intensity distribution at the time of reverse bias in the termination region of the second comparative example. The figure illustrates a schematic cross-sectional diagram of the termination region of the PIN diode 900 and the electric field intensity distribution. The dotted line indicates the electric field intensity distribution before applying stress, and the solid line indicates the electric field intensity distribution after applying stress.

The electric field intensity distribution before applying stress represents that the electric field intensity distribution is almost uniform in the termination region. On the other hand, the electric field intensity distribution after applying stress represents that the electric field intensity distribution is not uniform in the termination region. Particularly, in the inner circumferential portion of the termination region being near to the active region, the electric field intensity becomes strong. In a case when an amount of the negative charges included in the insulating film is large and the electric field intensity of the inner circumferential portion become larger than a threshold value, a decrease in breakdown voltage or an increase in leakage current of the PIN diode 900 occurs. Or, in a case when the influence of extraneous charges or interface charges are added to the influence of the negative charges included in the insulating film, the electric field intensity of the inner circumferential portion may exceed the threshold value, and a decrease in breakdown voltage or an increase in leakage current of the PIN diode 900 occurs.

It is considered that the change in electric field intensity distribution occurs because the negative charges in the second insulating film 26 are moved by the electric field applied to the second insulating film 26.

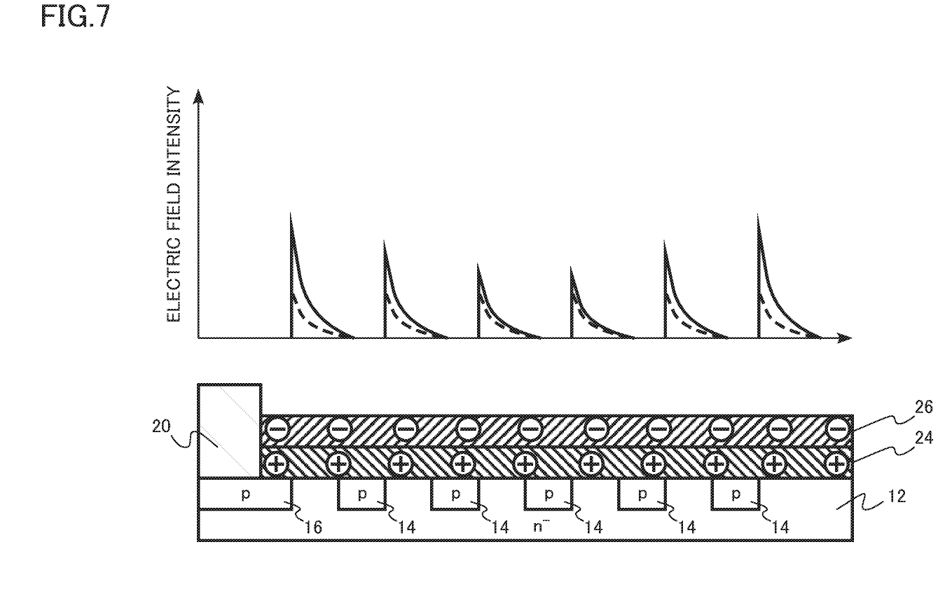

FIG. 7 is a schematic diagram illustrating an electric field intensity distribution at the time of reverse bias in the termination region according to the embodiment. The figure illustrates a schematic cross-sectional diagram of the termination region of the PIN diode 100 and the electric field intensity distribution. The dotted line indicates the electric field intensity distribution before applying stress, and the solid line indicates the electric field intensity distribution after applying stress.

The electric field intensity distribution before applying stress represents that the electric field intensity distribution is almost uniform in the termination region. On the other hand, although the electric field intensity distribution after applying stress represents that the electric field intensity distribution is not uniform in the termination region, the positions where the electric field intensity becomes strong are distributed over the outer and inner portions of the termination region. Therefore, in comparison with the first and second comparative examples, the maximum electric field intensity of the termination region is lowered. Therefore, a decrease in breakdown voltage or an increase in leakage current of the PIN diode 100 is suppressed. In this manner, since the maximum electric field intensity of the termination region is allowed to be lowered, even in a case where interface charges or extraneous charges exist, the electric field intensity of the termination region does not exceed a threshold value, and thus, a decrease in breakdown voltage or an increase in leakage current of the PIN diode 100 is suppressed.

According to the PIN diode 100 of the embodiment, change in electric field intensity after applying stress is suppressed, so that reliability is improved.

### Second Embodiment

A semiconductor device according to this embodiment is the same as that of the first embodiment except that the upper and lower position between the first insulating film and the second insulating film are inverted. Therefore, redundant description of the same components as those of the first embodiment is omitted.

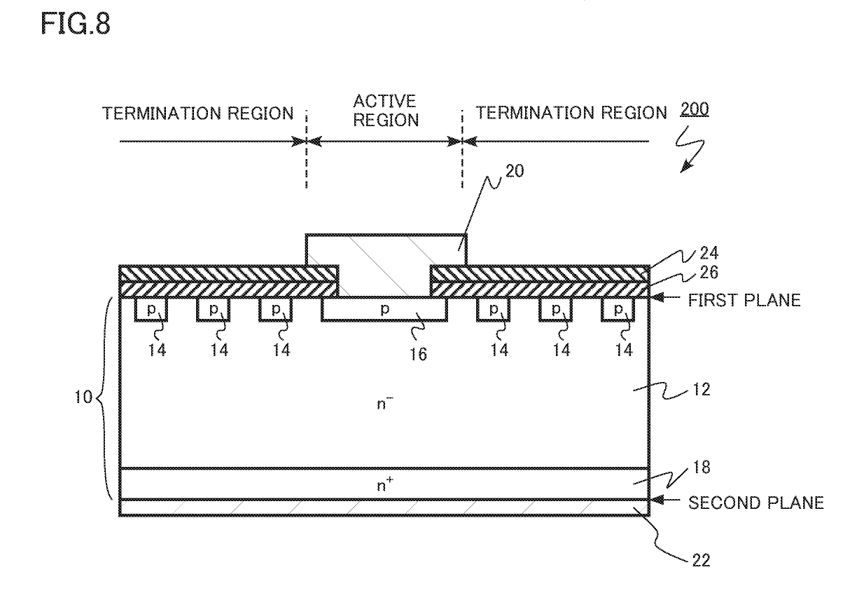

FIG. 8 is a schematic cross-sectional diagram of the semiconductor device according to the embodiment. The semiconductor device according to the embodiment is a vertical type PIN diode 200.

The PIN diode 200 is configured to include a silicon substrate (semiconductor substrate) 10, an anode electrode (first electrode) 20, a cathode electrode (second electrode) 22, a first interlayer insulating film (first insulating film) 24, and a second interlayer insulating film (second insulating film) 26. The semiconductor substrate 10 is configured to include an n⁻ type drift region (first region) 12, p type guard ring regions (second regions) 14, a p type anode region 16, and an n⁺ type cathode region 18.

The first interlayer insulating film 24 is formed on the second interlayer insulating film 26 to be in contact with the second interlayer insulating film 26.

According to the PIN diode 200 of the embodiment, by the same functions as those of the first embodiment, change in electric field intensity after applying stress is suppressed, so that reliability is improved.

### Third Embodiment

A semiconductor device according to this embodiment is the same as that of the first embodiment except that a third insulating film is further included between the first and second insulating films and the semiconductor substrate. Therefore, redundant description of the same components as those of the first embodiment is omitted.

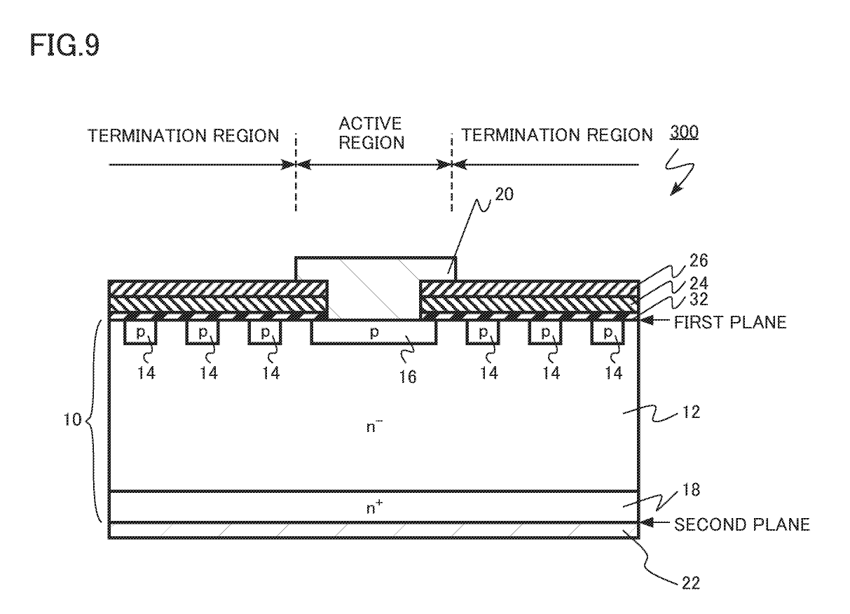

FIG. 9 is a schematic cross-sectional diagram of the semiconductor device according to the embodiment. The semiconductor device according to the embodiment is a vertical type PIN diode 300.

The PIN diode 300 is configured to include a silicon substrate (semiconductor substrate) 10, an anode electrode (first electrode) 20, a cathode electrode (second electrode) 22, a first interlayer insulating film (first insulating film) 24, and a second interlayer insulating film (second insulating film) 26. The semiconductor substrate 10 is configured to include an n⁻ type drift region (first region) 12, p type guard ring regions (second regions) 14, a p type anode region 16, and an n⁺ type cathode region 18. The PIN diode 300 is configured to further include a surface oxide film (third insulating film) 32.

The surface oxide film 32 is provided between the first interlayer insulating film 24 and the silicon substrate 10 and between the second interlayer insulating film 26 and the silicon substrate 10. The surface oxide film 32 is formed in the first plane of the silicon substrate 10 to be contact with the first plane.

The surface oxide film 32 is, for example, a thermally oxidized film of silicon. The thickness of the surface oxide film 32 is, for example, 0.01 μm or more and 0.1 μm or less.

According to the PIN diode 300 of this embodiment, by the same functions as those of the first embodiment, a change in electric field intensity after applying stress is suppressed, so that reliability is improved.

In the embodiment, the structure having the first to third insulating films are described above. The number of insulating films is not limited thereto, but a plurality of insulating films including positive charges may be employed. In addition, a plurality of insulating films including negative charges may be employed.

### Fourth Embodiment

A semiconductor device according to this embodiment is different from that of the first embodiment in terms that the semiconductor device is an insulated gate bipolar transistor (IGBT). Hereinafter, redundant description of the same components as those of the first embodiment is omitted.

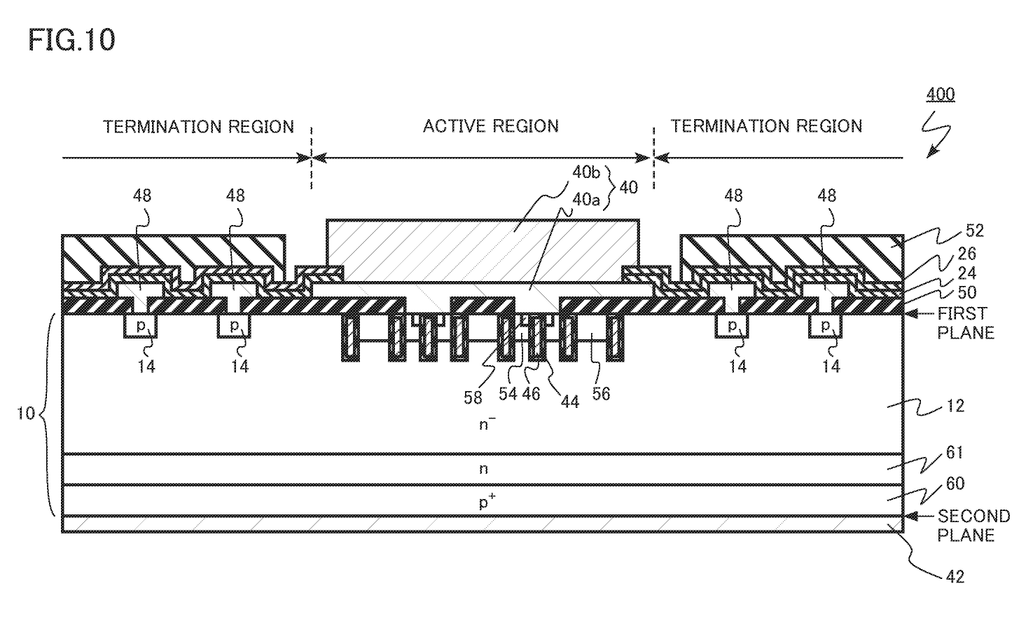

FIG. 10 is a schematic cross-sectional diagram of the semiconductor device according to the embodiment. The semiconductor device according to the embodiment is a vertical type IGBT 400. The semiconductor device according to the embodiment is an injection enhanced gate transistor (IEGT) having a structure of increasing an on-state accumulation carrier density of an n type drift region at an emitter side. The IGBT 400 is, for example, a high breakdown voltage IEGT having a breakdown voltage of 4.5 kV or more and used for press pack IEGT (PPI). All electric connections of the PPI are formed by applying pressure. The breakdown voltage is not limited to 4.5 kV or more, but for example, the embodiment may be applied to a semiconductor device requiring a breakdown voltage of 600 V or more.

The IGBT 400 is configured to include an active region and a termination region surrounding the active region. The active region functions as a region where current flows mainly at the time of on-operation of the IGBT 400. The termination region functions as a region of alleviating an intensity of an electric field applied to the end portion of the active region at the time of off-operation of the IGBT 400 to improve an device breakdown voltage of the IGBT 400.

The IGBT 400 is configured to include a silicon substrate (semiconductor substrate) 10, an emitter electrode (first electrode) 40, collector electrodes (second electrodes) 42, gate insulating films 44, gate electrodes 46, field plate electrodes 48, surface insulating films (third insulating films) 50, a first interlayer insulating film (first insulating film) 24, a second interlayer insulating film (second insulating film) 26, and a passivation film 52. The semiconductor substrate 10 is configured to include an n⁻ type drift region (first region) 12, p type guard ring regions (second regions) 14, a p type base region 54, a p type floating region 56, an n⁺ type emitter region 58, and a p⁺ type collector region 60.

The silicon substrate 10 has a first plane and a second plane facing the first plane. In FIG. 10, the first plane is the surface in the upper portion of the figure, and the second plane is the surface in the lower portion of the figure. At least a portion of the silicon substrate 10 is provided between the emitter electrode 40 and the collector electrode 42.

The p⁺ type collector region 60 is formed in the silicon substrate 10. The p⁺ type collector region 60 is formed to be in contact with the second plane of the silicon substrate 10.

The p⁺ type collector region 60 contains p type impurities. The p type impurity is, for example, boron (B).

The n type buffer region 61 is formed in the silicon substrate 10. The n type buffer region 61 is formed to be in contact with the surface of the side of the p⁺ type collector region facing the second plane.

The n type buffer region 61 contains n type impurities. The n type impurity is, for example, phosphorus (P) or arsenic (As).

The n⁻ type drift region 12 is formed in the silicon substrate 10. The n⁻ type drift region 12 is formed between the n type buffer region 61 and the first plane.

The n⁻ type drift region 12 contains n type impurities. The n type impurity is, for example, phosphorus (P) or arsenic (As).

The p type base region 54 and p type floating region 56 are formed in the silicon substrate 10. The p type base region 54 and the p type floating region 56 are formed in the active region. The p type base region 54 and the p type floating region 56 are formed between the n⁻ type drift region 12 and the first plane.

The p type base region 54 and the p type floating region 56 contain p type impurities. The p type impurity is, for example, boron (B).

The n⁺ type emitter region 58 is formed in the silicon substrate 10. The n⁺ type emitter region 58 is formed in the active region. The n⁺ type emitter region 58 is formed between the p type base region 54 and the first plane. The n⁺ type emitter region 58 is formed to be in contact with the gate insulating film 44 and the first plane.

The n⁺ type emitter region 58 contains n type impurities. The n type impurity is, for example, phosphorus (P) or arsenic (As).

The gate insulating film 44 is formed in the inner surface of a trench formed in the silicon substrate 10. The trench is formed in the active region. The gate insulating film 44 is, for example, a silicon oxide film.

The gate electrode 46 is formed in the trench formed in the silicon substrate 10. The gate electrode 46 is formed on the gate insulating film 44. The gate electrode 46 is, for example, polycrystalline silicon doped with n type impurities.

A plurality of the p type guard ring regions 14 are formed in the silicon substrate 10. The p type guard ring regions 14 are formed in the termination region. The p type guard ring regions 14 are formed to be in contact with the first plane of the silicon substrate 10. The p type guard ring regions 14 are formed between the n⁻ type drift region 12 and the first plane of the silicon substrate 10.

In addition, as illustrated in FIG. 10, the p type guard ring regions 14 are formed around the region where the emitter electrode 40 is in contact with the first plane of the silicon substrate 10. The p type guard ring regions 14 have a ring shape surrounding the active region.

The p type guard ring regions 14 contain p type impurities. The p type impurity is, for example, boron (B).

In FIG. 10, although the number of p type guard ring regions 14 is set to 2, the number of p type guard ring regions 14 is not necessarily limited to 2. The number of p type guard ring regions 14 is determined according to the breakdown voltage level or the like required for the IGBT 400. The number of p type guard ring regions 14 is, for example, 10 or more and 30 or less.

In addition, in FIG. 10, although the width of the p type guard ring regions 14 is set to a constant value, the width or interval of p type guard ring regions 14 is not limited to the constant value. The width and intervals of the p type guard ring regions 14 are determined according to the breakdown voltage level or the like required for the IGBT 400. For example, the interval of p type guard ring regions 14 is set to be narrow at the side close to the active region and to be widened as being apart from the active region.

The surface insulating films 50 are formed in the first plane of the silicon substrate 10 to be in contact with the first plane. The surface insulating films 50 are, for example, silicon films formed by a CVD method using TEOS as a source gas. The thickness of each of the surface insulating films 50 are, for example, 0.1 μm or more and 2.0 μm or less.

The field plate electrodes 48 are formed on the surface insulating films 50. The field plate electrodes 48 are in contact with the p type guard ring regions 14 at the bottom of the openings formed in the surface insulating films 50. The field plate electrodes 48 are floating. The field plate electrodes 48 have a function of alleviating an electric field of the termination region.

The first interlayer insulating film 24 is formed in the first plane of the silicon substrate 10. The first interlayer insulating film 24 is formed on the p type guard ring regions 14. The first interlayer insulating film 24 is formed on the field plate electrodes 48.

The first interlayer insulating film 24 includes positive charges in the film. The amount of positive charges is, for example, 1E10 cm⁻² or more 1E12 cm⁻² or less. The first interlayer insulating film 24 is, for example, an oxide film. The first interlayer insulating film 24 is, for example, a silicon oxide film.

The thickness of the first interlayer insulating film 24 is, for example, 0.1 μm or more and 2.0 μm or less.

The second interlayer insulating film 26 is formed in the first plane of the silicon substrate 10. The second interlayer insulating film 26 is formed on the p type guard ring regions 14. In the embodiment, the second interlayer insulating film 26 is formed on the first interlayer insulating film 24 to be in contact with the first interlayer insulating film 24,

The second interlayer insulating film 26 includes negative charges in the film. The amount of negative charges is, for example, 1E10 cm⁻² or more 1E12 cm⁻² or less. The second interlayer insulating film 26 is, for example, an oxide film. The second interlayer insulating film 26 is, for example, a silicon oxide film.

The thickness of the second interlayer insulating film 26 is, for example, 0.1 μm or more and 2.0 μm or less.

The emitter electrode 40 is formed on the silicon substrate 10. The emitter electrode 40 is formed to be in contact with a portion of the first plane of the silicon substrate 10.

The emitter electrode 40 is formed to be in contact with the n⁺ type emitter region 58. The contact between the emitter electrode 40 and the n⁺ type emitter region 58 is an ohmic contact.

The emitter electrode 40 includes a lower electrode 40a and an upper electrode 40b. The first interlayer insulating film 24 and the second interlayer insulating film 26 are formed in a portion of the space between the lower electrode 40a and the upper electrode 40b.

In the emitter electrode 40, both of the lower electrode 40a and the upper electrode 40b are metals. The lower electrode 40a and the upper electrode 40b are stacked films of, for example, titanium (Ti), titanium nitride (TiN), and aluminum (Al).

The collector electrode 42 is formed to be in contact with the second plane of the silicon substrate 10.

The collector electrode 42 is formed to be in contact with the collector region 60. The contact between the collector electrode 42 and the collector region 60 is an ohmic contact.

The collector electrode 42 is a metal. The collector electrode 42 is a stacked film of, for example, aluminum containing silicon (AlSi), titanium (Ti), nickel (Ni), and silver (Ag).

The passivation film 52 is formed on the second interlayer insulating film 26. The passivation film 52 is, for example, a resin film. The passivation film 52 is, for example, a polyimide film.

Similarly to the PIN diode 100 according to the first embodiment, the IGBT 400 according to the embodiment is also configured to include the termination region including the first interlayer insulating film 24 including positive charges and the second interlayer insulating film 26 including negative charges. Therefore, by the same functions as those of the first embodiment, change in electric field intensity after applying stress is suppressed, so that reliability is improved.

In addition, since the surface insulating films 50 are separated by the field plate electrodes 48, the movement of the charges in the surface insulating films 50 is suppressed. Therefore, a change in electric field intensity distribution of the termination region according to the movement of the charges in the surface insulating films 50 is so small that the change can be neglected.

In the first to fourth embodiments, although the examples where PIN diodes and IGBTs are used as semiconductor devices are described, the present invention may be applied to other semiconductor devices such as a Schottky barrier diode and a MOSFET (Metal Oxide Semiconductor Field Effect Transistor).

In the first to fourth embodiments, silicon oxide films are exemplified as the first insulating film and the second insulating film. However, the first insulating film and the second insulating film are not limited to the silicon oxide films. For example, a silicon nitride film, a silicon oxynitride film, or the like may be used as the first insulating film or the second insulating film. In addition, for example, a high-k film such as a hafnium oxide film, an aluminum oxide film, or a zirconium oxide film may be used as the first insulating film or the second insulating film.

In the first to fourth embodiments, although a case where the first conductivity-type is n type and the second conductivity-type is p type is exemplified, the present invention may be applied to a semiconductor device where the first conductivity-type is p type and the second conductivity-type is n type.

In the first to fourth embodiments, although the example where a silicon substrate is used as the semiconductor substrate is described, other semiconductor substrates such as a silicon carbide substrate and a nitride semiconductor substrate may be used as the semiconductor substrate.

While certain embodiments have been described, these embodiments have been presented by way of example only, and are not intended to limit the scope of the inventions. Indeed, a semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a first electrode;
a second electrode;
a semiconductor substrate having a first plane, a second plane, a first conductivity-type first region, and a plurality of second conductivity-type second regions provided around the first electrode, the second regions being in contact with the first plane, at least a portion of the semiconductor substrate being provided between the first electrode and the second electrode;
a first insulating film provided on or above the second regions, the first insulating film including positive charges; and
a second insulating film provided on or above the second regions, the second insulating film including negative charges.

2. The semiconductor device according to claim 1, wherein the first insulating film and the second insulating film are silicon oxide films.

3. The semiconductor device according to claim 1, wherein a carbon concentration of the first insulating film is higher than a carbon concentration of the second insulating film.

4. The semiconductor device according to claim 1, further comprising a third insulating film provided between the first insulating film and the semiconductor substrate, and between the second insulating film and the semiconductor substrate.

5. The semiconductor device according to claim 1, wherein the first insulating film is a silicon oxide film formed by a chemical vapor deposition (CVD) method using tetraethyl orthosilicate (TEOS) as a source gas.

6. The semiconductor device according to claim 1, wherein the second insulating film is a silicon oxide film formed by a high density plasma-CVD (HDP-CVD) method.

7. The semiconductor device according to claim 1, wherein the first insulating film and the second insulating film are in contact with each other.

8. The semiconductor device according to claim 1, wherein the semiconductor substrate is a silicon substrate.

9. The semiconductor device according to claim 1, wherein the first insulating film is provided between the semiconductor substrate and the second insulating film.

10. The semiconductor device according to claim 1, wherein the second insulating film is provided between the semiconductor substrate and the first insulating film.

11. The semiconductor device according to claim 2, wherein the semiconductor substrate is a silicon substrate.

12. The semiconductor device according to claim 3, wherein the semiconductor substrate is a silicon substrate.

13. The semiconductor device according to claim 11, wherein a carbon concentration of the first insulating film is higher than a carbon concentration of the second insulating film.

14. The semiconductor device according to claim 11, wherein the first insulating film is a silicon oxide film formed by a CVD method using TEOS as a source gas.

15. The semiconductor device according to claim 11, wherein the second insulating film is a silicon oxide film formed by an HDP-CVD method.

16. The semiconductor device according to claim 15, wherein first insulating film is a silicon oxide film formed by a CVD method using TEOS as a source gas.

17. The semiconductor device according to claim 16, wherein a carbon concentration of the first insulating film is higher than a carbon concentration of the second insulating film.

18. The semiconductor device according to claim 17, wherein the first insulating film and the second insulating film are in contact with each other.
